(19) United States
(12) Patent Application Publication
(10) Pub. No.: US 2008/0029027 A1
(43) Pub. Date: Feb. 7, 2008

(54) Plasma Cvd Device

(75) Inventors: Teruhiko Kumada, Tokyo (JP); Naoki Yasuda, Tokyo (JP); Hideharu Nobutoki, Tokyo (JP); Norihisa Matsumoto, Tokyo (JP); Shigeru Matsuno, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku, Tokyo (JP)

(21) Appl. No.: 11/577,008

(22) PCT Filed: Oct. 7, 2005
(86) PCT No.: PCT/JP05/18615

§ 371 Date: Apr. 11, 2007

(30) Foreign Application Priority Data
Oct. 19, 2004 (JP) 2004-304015

(51) Int. Cl. C23C 16/00

(52) U.S. Cl. 118/715

(57) ABSTRACT

The present invention provides a plasma CVD device including means for supplying a compound with borazine skeleton, a plasma generator for generating a plasma, and means for applying a negative charge to an electrode for placing a substrate. According to the present invention, it is possible to provide a plasma CVD device which stably provides a low dielectric constant and a high mechanical strength over a long period of time, reducing the amount of a gas component (outgas) emitted in heating the film, and causing no trouble in a device manufacturing process.

### TECHNICAL FIELD

The present invention relates to a plasma Chemical Vapor Deposition (CVD) device.

### BACKGROUND ART

As a semiconductor element achieves a higher speed and a more highly integrated structure, a problem of a signal delay becomes more and more serious. The signal delay is represented by a product of wiring resistance, and interwire and interlayer capacitance. In order to minimize the signal delay, decreasing a dielectric constant of an interlayer insulating film as well as reducing the wiring resistance is an effective measure.

Recently, as a method of decreasing a dielectric constant of an interlayer insulating film, there has been disclosed a method of forming, at a surface of a body to be processed, an interlayer insulating film containing a B—C—N linkage by plasma CVD in an atmosphere containing a hydrocarbon-based gas, borazine, and a plasma-based gas. Furthermore, it is disclosed that the interlayer insulating film has a low dielectric constant (e.g. see Japanese Patent Laying-Open No. 2000-058538 (Patent Document 1)).

However, the conventional method above uses borazine as a CVD raw material, and hence, although there can be formed a film having a low dielectric constant and a high mechanical strength, these characteristics do not continue because of its poor water resistance. Furthermore, in a heating treatment associated with a process of manufacturing a device by utilizing a substrate where the film is formed, a gas component is generated from the film to exert an adverse effect on the device manufacturing process.

Patent Document 1: Japanese Patent Laying-Open No. 2000-058538

### DISCLOSURE OF THE INVENTION

### Problems to be Solved by the Invention

The present invention is made to solve the problems above in the conventional technique. An object of the present invention is to provide a plasma CVD device capable of manufacturing a film, which stably provides a low dielectric constant and a high mechanical strength over a long period of time, which has a reduced amount of a gas component (outgas) emitted when it is heated, and which avoids any trouble in a device manufacturing process.

### Means for Solving the Problems

A plasma CVD device according to the present invention is characterized in that it includes means for supplying a compound with borazine skeleton, a plasma generator for generating a plasma, and means for applying a negative charge to an electrode for placing a substrate.

Preferably, the compound with borazine skeleton is herein expressed by a chemical formula (1) below. 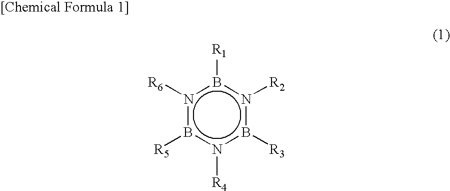
(In the formula, R₁—R₆ may be identical with or different from each other, and are each independently selected from a group consisting of a hydrogen atom, and an alkyl group, an alkenyl group and an alkynyl group each having a carbon number of 1-4, on condition that at least one of R₁—R₆ is not the hydrogen atom.) The plasma CVD device according to the present invention preferably includes a reaction container for forming a film on the substrate by plasma chemical vapor deposition and the plasma generator provided outside the reaction container, or includes the reaction container for forming a film on the substrate by plasma chemical vapor deposition and the plasma generator provided inside the reaction container.

If the plasma generator is provided inside the reaction container, it is preferable that the plasma generator is provided at the electrode for placing the substrate.

### EFFECTS OF THE INVENTION

With the plasma CVD device according to the present invention, it is possible to stably provide a low dielectric constant and a high mechanical strength over a long period of time, and also reduce the amount of an outgas from the obtained film in manufacturing the device. With the plasma CVD device according to the present invention, it is also possible to manufacture a film having a lower dielectric constant, an improved crosslink density, and an improved mechanical strength, when compared with the conventional one.

### BRIEF DESCRIPTION OF THE DRAWINGS

FIG. 1 schematically shows an example of a PCVD device according to the present invention.

FIG. 2 is a graph showing TDS data of a film formed in Example 1.

FIG. 3 is a graph showing TDS data of a film formed in Comparative Example 1.

FIG. 4 is a graph showing an example of an FT-IR spectrum shape of each of films formed on a power feed electrode side (solid line) and on a counter electrode side (dashed line).

### DESCRIPTION OF THE REFERENCE SIGNS

1 reaction container, 2 high-frequency power source, 3 matching box, 4 vacuum pump, 5 gas inlet, 6 heating/cooling device, 7 power feed electrode, 8 substrate, 9 counter electrode.

### BEST MODES FOR CARRYING OUT THE INVENTION

The plasma CVD device (PCVD device) according to the present invention is characterized in that it includes means for supplying a compound with borazine skeleton, a plasma generator for generating a plasma, and means for applying a negative charge to an electrode for placing a substrate. With the plasma CVD device according to the present invention, the negative charge is applied to the site of the substrate during CVD, so that the amount of the outgas emitted in heating the film manufactured by the relevant method is reduced, and no trouble occurs in the process of manufacturing the device utilizing the film.

The PCVD device according to the present invention is implemented such that the compound with borazine skeleton is supplied by, for example, a method of introducing the borazine compound into the device having a vaporization mechanism for heating the borazine compound left at a room temperature for vaporizing the same, a method of heating a container itself where the borazine compound is stored, to vaporize the borazine compound, and subsequently utilizing a pressure, which is increased by the vaporization of the borazine compound, to introduce the vaporized borazine compound into the device, a method of mixing Ar, He, nitrogen or another gas into the vaporized borazine compound to introduce the same into the device, or the like. Among these methods, from the viewpoint that heat denaturation of the raw material is less likely to occur, the PCVD device is preferably implemented such that the compound with borazine skeleton is supplied by the method of introducing the borazine compound into the device having a vaporization mechanism for heating the borazine compound left at a room temperature for vaporizing the same.

For the plasma generator in the PCVD device according to the present invention, there may be used, for example, an appropriate plasma generator such as a capacitively-coupled mode (parallel plate-type) plasma generator or an inductively-coupled mode (coil type) plasma generator. Among them, from the viewpoint that a practical film formation rate (10 nm/minute-5000 nm/minute) can easily be obtained, the capacitively-coupled mode (parallel plate-type) plasma generator is preferable.

Furthermore, if a plasma is generated between electrodes by using the capacitively-coupled type plasma generator in the relevant device, for example, the PCVD device according to the present invention is implemented such that a negative charge is applied to the electrode for placing the substrate, by a method of applying a radio frequency to the electrode for placing the substrate, or a method of applying a direct current having a frequency other than a radio frequency, or a radiofrequency alternating current, for generating a plasma, to the electrode for placing the substrate. Among these methods, from a viewpoint that it is possible to apply to the substrate a negative charge independent of an electric potential produced by the generated plasma, the PCVD device is preferably implemented such that a negative charge is applied to the electrode for placing the substrate, by the method of applying a direct current.

Any appropriate, conventionally-known compound may be used for the compound with borazine skeleton supplied in the PCVD device above, without any particular limitation, as long as it has borazine skeleton. However, a compound expressed by a chemical formula (1) below is preferably used as a raw material, particularly because it is possible to manufacture a film improved in dielectric constant, thermal expansion coefficient, heat resistance, thermal conductivity, mechanical strength, and the like.

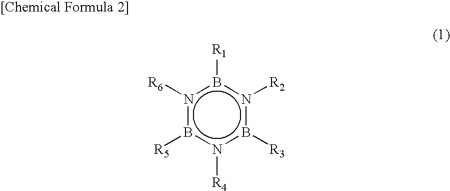

In the compound expressed by the chemical formula (1) above, substituent groups expressed by R₁—R₆ may be identical with or different from each other, and any of a hydrogen atom, and an alkyl group, an alkenyl group and an alkynyl group each having a carbon number of 1-4 may be used independently for the substituent groups. However, there is no case where all of R₁—R₆ are hydrogen atoms. If all of them are hydrogen, a boron-hydrogen linkage or a nitrogen-hydrogen linkage tends to remain in the film. These linkages have a high hydrophilicity, which disadvantageously results in increase in hygroscopicity of the film, so that a desired film may not be obtained. If each of the R₁—R₆ in the compound (1) above has a carbon number of more than 4, the formed film has a high content of carbon atoms, so that heat resistance and mechanical strength of the film may be deteriorated. The carbon number is more preferably 1 or 2.

The chemical vapor deposition method (CVD method) used for forming a film on the substrate by means of the PCVD device according to the present invention, will hereinafter be described. When the CVD method is used for film formation, the raw material gas described above forms the film by successive cross-linking, so that a high crosslink density can be obtained. Accordingly, the film is expected to have an increased mechanical strength.

In the CVD method, helium, argon, nitrogen or the like is used as a carrier gas to move the raw material gas of the compound with borazine skeleton (1), which is expressed by the chemical formula (1) above, to a neighborhood of the substrate where a film is to be formed.

At this time, it is also possible to mix methane, ethane, ethylene, acetylene, ammonia or a compound of alkylamines into the carrier gas to control the characteristic of the film to be formed to a desired characteristic.

The flow rate of the carrier gas may arbitrarily be set to fall within the range of 100-1000 sccm. The flow rate of the gas of the compound with borazine skeleton may arbitrarily be set to fall within the range of 1-300 sccm. The flow rate of methane, ethane, ethylene, acetylene, ammonia or alkylamines may arbitrarily be set to fall within the range of 0-100 sccm.

If the flow rate of the carrier gas is less than 100 sccm, an extremely long period of time is required for obtaining a desired film thickness, and there may also be a case where film formation does not proceed. If the flow rate exceeds 1000 sccm, uniformity of the film thickness on the substrate tends to be reduced. The flow rate is more preferably at least 20 sccm and at most 800 sccm.

If the flow rate of the gas of the compound with borazine skeleton is less than 1 sccm, an extremely long period of time is required for obtaining a desired film thickness, and there may also be a case where film formation does not proceed. If the flow rate exceeds 300 sccm, the obtained film has a low crosslink density, and hence a lowered mechanical strength. The flow rate is more preferably at least 5 sccm and at most 200 sccm.

The flow rate of the gas of methane, ethane, ethylene, acetylene, ammonia or alkylamines exceeds 100 sccm, the obtained film has a high dielectric constant. The flow rate is more preferably at least 5 sccm and at most 100 sccm.

As described above, the raw material gas carried to the neighborhood of the substrate is deposited on the substrate through a chemical reaction, so that the film is formed. In order to efficiently cause the chemical reaction, a plasma is used in combination during CVD in the present invention. An ultraviolet ray, an electron beam or the like may further be used in combination.

It is preferable to heat, during CVD, the substrate where the film is to be formed, because an outgas can be reduced more easily. If heat is used for heating the substrate, each of the gas temperature and the substrate temperature is controlled to fall within the range from a room temperature to 450° C. If each of the raw material gas temperature and the substrate temperature exceeds 450° C., an extremely long period of time is required for obtaining a desired film thickness, and there may also be a case where film formation does not proceed. Each of the temperatures is more preferably at least 50° C. and at most 400° C.

If a plasma is used for heating the substrate, the substrate is placed in, for example, a parallel plate-type plasma generator, and the raw material gas is then introduced thereinto. The frequency and the power of an RF used at this time may arbitrarily be set at 13.56 MHz or 400 kHz, and may arbitrarily be set to fall within the range of 5-1000 W, respectively. Alternatively, it is also possible to use in combination RFs having these different frequencies.

If the power of the RF used for performing plasma CVD exceeds 1000 W, there is increased the frequency with which the compound with borazine skeleton expressed by the chemical formula (1) is decomposed by the plasma, so that it becomes difficult to obtain a film having a desired borazine structure. The power is more preferably at least 10 W and at most 800 W.

In the present invention, the pressure in the reaction container is preferably set to be at least 0.01 Pa and at most 10 Pa. If the pressure is less than 0.01 Pa, there is increased the frequency with which the compound with borazine skeleton is decomposed by the plasma, so that it becomes difficult to obtain a film having a desired borazine structure. If the pressure exceeds 10 Pa, the obtained film has a low crosslink density, and hence a low mechanical strength. The pressure is more preferably at least 5 Pa and at most 6.7 Pa. Note that the pressure can be adjusted by means of a pressure regulator such as a vacuum pump, or by changing a gas flow rate.

Preferably, the PCVD device according to the present invention further includes a reaction container for forming the film on the substrate by PCVD. In such a configuration further including the reaction container, there may adopt any of a configuration where the plasma generator is provided outside the reaction container, and a configuration where the plasma generator is provided inside the reaction container. In the configuration where the plasma generator is provided outside the reaction container, for example, the plasma does not directly affect the substrate, and hence there is an advantage that it is possible to prevent the progress of an unexpected reaction caused by excessive exposure of the film, which is produced on the substrate, to an electron, an ion, a radical or the like in the plasma. In the configuration where the plasma generator is provided inside the reaction container, there is an advantage that a practical film formation rate (10 nm/minute-5000 nm/minute) can easily be obtained.

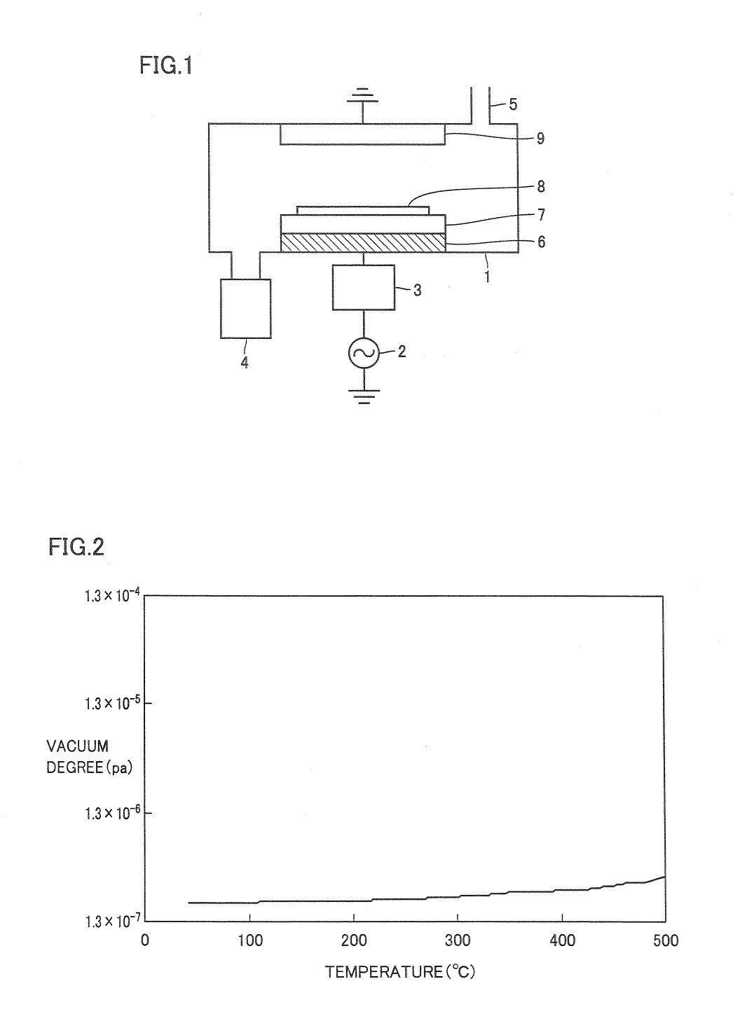

FIG. 1 schematically shows a preferable example of the PCVD device according to the present invention. The PCVD device according to the present invention adopts the configuration where a plasma generator is provided inside the reaction container described above. Furthermore, it is particularly preferable that the PCVD device is implemented by a parallel plate-type PCVD device where the plasma generator is provided at an electrode for placing a substrate, by utilizing a capacitively-coupled mode. By using such a PCVD device, the film is formed on an applying electrode side (by a negative bias), and hence it is considered that a positive-ionized borazine molecule generated in the plasma, or He, Ar or the like used as the carrier gas, impinges on a borazine molecule deposited on the substrate to generate a new active spot, which enables further progress of a cross-linking reaction. In contrast, if the film is formed on a counter electrode side (by a positive bias), more of the electrons generated in the plasma scatter, when compared with the case where the film is formed on the applying electrode side, and the electrons impinge on a borazine molecule deposited on the substrate, inevitably resulting in more radicals. The generated radicals have less activity, when compared with the ones generated by ion impingement, so that it is considered that a sufficient crosslink density is difficult to obtain.

In the PCVD device shown in FIG. 1, a reaction container 1 is provided with a power feed electrode 7 with a heating/cooling device 6 interposed therebetween, and a substrate 8, to which a film is to be formed, is disposed on power feed electrode 7. Heating/cooling device 6 can heat or cool substrate 8 to a prescribed processing temperature. Power feed electrode 7 is connected to a high-frequency power source 2 via a matching box 3, which makes it possible to adjust an electric potential to a prescribed one.

In reaction container 1 in FIG. 1, a counter electrode 9 is provided on a side opposite to substrate 8. A gas inlet 5 and a vacuum pump 4 for ejecting a gas inside reaction container 1 are further provided.

As to substrate 8 where a film is to be grown in reaction container 1 for generating a plasma, substrate 8 is placed at power feed electrode 7 for inducing a plasma to perform film formation, so that a desired film can be formed. At this time, by imparting an electric potential onto counter electrode 9 opposite to power feed electrode 7 from another high-frequency power source, it is also possible to arbitrarily adjust the electric potential on substrate 8 where a film is to be formed. In this case, the present invention is characterized in that power feed electrode 7 on the side of substrate 8 is set at a negative electric potential.

If the film is to be grown in a film forming device using a dense plasma source, a desired film may be formed by using a power source independent of high-frequency power source 2 serving as a plasma source and applying a negative charge to the substrate.

The PCVD device shown in FIG. 1 is configured such that counter electrode 9 is located on an upper side of the device, while power feed electrode 7 is located on an lower side of the device. However, these electrodes are only required to be located to face each other, and a vertically-reverse configuration, for example, may of course be possible (in this case, substrate 8 has a structure allowing itself to be supported by a substrate fixing part such as a flat spring, a screw, a pin or the like, so that it is fixed to power feed electrode 7. Here, a susceptor substrate may also be placed at power feed electrode 7 directly. Alternatively, substrate 8 may also be fixed to power feed electrode 7 via a jig for transporting a substrate.).

Film formation by using the PCVD device according to the present invention in the example shown in FIG. 1 will be described. In FIG. 1, substrate 8 is initially disposed on power feed electrode 7 and reaction container 1 is evacuated. A raw material gas, a carrier gas, and another gas described above, as needed, are then supplied to reaction container 1 through gas inlet 5. The flow rate used when each of the gases are supplied is as described above. In addition to this, the pressure in reaction container 1 is maintained to a prescribed processing pressure by evacuating reaction container 1 by means of vacuum pump 4. Furthermore, substrate 8 is set to a prescribed processing temperature by means of heating/cooling device 6.

A negative charge is applied to power feed electrode 7 by means of high-frequency power source 2 to generate a plasma in the gases in reaction container 1. In the plasma, the raw material gas and the carrier gas are turned into ions and/or radicals, which are successively deposited on substrate 8 to form a film.

Among them, the ion is attracted to the electrode at an electric potential opposite to an electric charge owned by the ion itself, and repeatedly impinges on the substrate to cause a reaction. In other words, in relation to an electric charge, a cation is attracted to a side of power feed electrode 7, whereas an anion is attracted to a side of counter electrode 9.

In contrast, the radicals are uniformly distributed in a plasma field. Accordingly, if a film is formed on the side of power feed electrode 7, many reactions are caused mainly by a cation, and hence a contribution of radical species to film formation is decreased.

Accordingly, it is possible in the present invention to reduce the amount of a radical remaining in the formed film by adjusting an electric potential of the electrodes, as described above, and hence there is suppressed a reaction between the radical remaining in the film and a substance such as oxygen or water in the air, which substance is active toward the radical, after the substrate is removed from the PCVD device.

If the radical remains in the film, the reaction between the borazine radical and oxygen or water occurs when the film is heated, so that B-hydroxyborazine is produced. Furthermore, B-hydroxyborazine further reacts with water in the air to produce boroxin and ammonia, so that the radical in the film makes brittle a part of the film, which tends to produce an outgas. However, in the film formation by using the PCVD device according to the present invention, radical species in the film are reduced, and hence the film formed by the method according to the present invention has a small amount of remaining radical, which makes it possible to reduce the amount of an outgas.

In the parallel plate-type PCVD device shown in FIG. 1, an example of the frequency of electric power to be applied is 13.56 MHz. However, an HF (a few tens-a few hundreds kHz), a microwave (2.45 GHz), or an ultrashort wave of 30 MHz-300 MHz may be used. If the microwave is used, there may be used a method of exciting the reaction gas to form a film in an afterglow, or ECR plasma CVD in which the microwave is introduced into a magnetic field that satisfies an ECR condition.

With the film formation by using the PCVD device according to the present invention, a film having a lower dielectric constant can be implemented when compared with a film using a conventional compound with borazine skeleton as a raw material. Here, “low dielectric constant” means that a certain dielectric constant can be maintained over a long period of time in a stable manner. Specifically, the film formed by the conventional manufacturing method maintains a dielectric constant of approximately 3.0-1.8 for a few days, whereas the film according to the present invention can maintain the above-described dielectric constant for at least a few years. The low dielectric constant can be confirmed, for example, by measuring the dielectric constant of the film stored for a certain period, with a method similar to that used immediately after the film formation.

The film formed by using the PCVD device according to the present invention can implement a higher crosslink density, when compared with the film obtained by the conventional PCVD device, and is a closely-packed film with improved mechanical strength (modulus of elasticity, strength or the like). The improvement in crosslink density can be confirmed from an FT-IR spectrum shape, for example, in which a peak adjacent to 1400 cm⁻¹ is shifted to a low frequency side. FIG. 4 shows an example of this FT-IR spectrum. It can be seen that the peak of an FT-IR spectrum shape of the film on the power feed electrode side (shown by a solid line in this drawing) is shifted to a low frequency side with respect to the peak of an FT-IR spectrum shape of the film on the counter electrode side (shown by a dashed line in this drawing).

The present invention will hereinafter be described in detail by providing examples. However, the present invention is not intended to be limited thereto.

### EXAMPLE 1 AND COMPARATIVE EXAMPLE 1

The parallel plate-type plasma CVD device in the example shown in FIG. 1 was used to form a film as follows. Helium was used as a carrier gas, and charged into a reaction container with a flow rate set to be 200 sccm. Furthermore, a B,B,B,N,N,N-hexamethylborazine gas serving as a raw material gas was introduced into the reaction container, where a substrate was placed, through a heated gas inlet, with a flow rate set to be 10 sccm. The steam temperature of the B,B,B,N,N,N-hexamethylborazine gas was 150° C. The substrate temperature was raised to 100° C., and a radiofrequency current of 13.56 MHz was applied to reach 150 W from a power feed electrode side, where the substrate was placed. The pressure in the reaction container was maintained at 2 Pa. By doing so, a film was formed on the substrate.

While the temperature of the obtained film on the substrate was raised at a rate of 60° C./minute, the amount of an outgas was measured by a thermal desorption spectroscopy (TDS) device. For the case where a substrate was placed on a counter electrode side (Comparative Example 1), there was measured, for comparison, the amount of an outgas from a film obtained concurrently with the above-described film, by means of the TDS.

For a measurement condition, each of the substrates were cut into a chip of a one centimeter square, and a comparison was made between the outgases emitted from the films thereon. FIG. 2 shows a vacuum degree of the film formed on the supply electrode side by the method according to the present invention, when the temperature of the film was raised. In FIG. 2, the vertical axis represents a vacuum degree (Pa), while the horizontal axis represents a temperature (° C.).

FIG. 2 shows that the outgas emitted from the film is increased with increasing vacuum degree. No obvious change in vacuum degree can be seen until the temperature reaches approximately 400° C., which shows that no outgas is generated by heating.

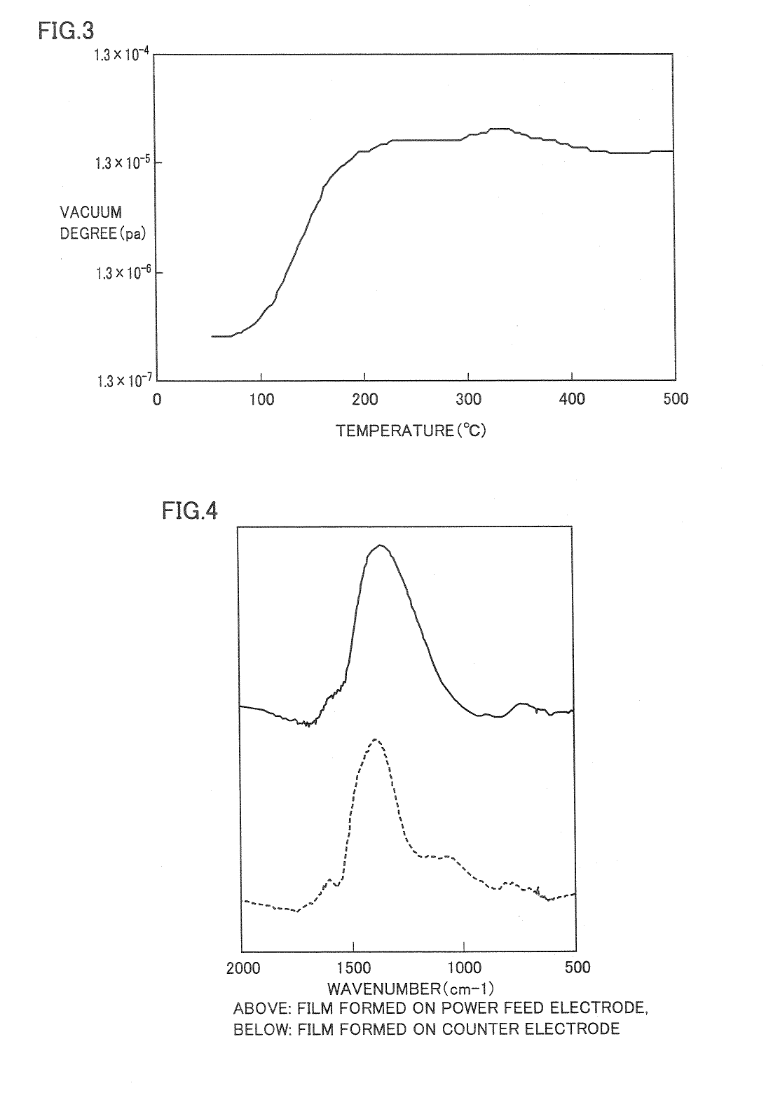

For comparison, FIG. 3 shows TDS data of the film formed on the counter electrode side. In FIG. 3, the vertical axis represents a vacuum degree (Pa), while the horizontal axis represents a temperature (° C). In FIG. 3, a vacuum degree is increased at a temperature of 100° C. or higher, which shows that an outgas is generated when the film is formed on the counter electrode side. In view of these, it was found that a film emitting less outgas can be formed by placing a substrate, where the film is to be formed, on the power feed electrode and maintaining the substrate at a negative electric potential.

### EXAMPLES 2-13, COMPARATIVE EXAMPLES 2-13

A TDS measurement was performed on a film formed of a modified type of the raw material gas, by a method similar to that of Example 1. Table 1 shows the results of Examples 2-9 (the case where the film was formed on the power feed electrode side), while Table 2 shows the results of Comparative Examples 2-9 (the case where the film was formed on the counter electrode side). Furthermore, Table 3 shows the results of Examples 10-13 (the case where the film was formed on the power feed electrode side), while Table 4 shows the results of Comparative Examples 10-13 (the case where the film was formed on the counter electrode side).

TABLE 1

| | Example 2 | Example 3 | Example 4 | Example 5 | Example 6 | Example 7 | Example 8 | Example 9 |
|---|---|---|---|---|---|---|---|---|
| Raw | N,N,N- | B,B,B- | B,B,B- | B,B,B- | B,B,B- | B,N,N,N- | B,B,B,N,N,N- | borazine |
| Material | trimethyl | triethyl | triethyl- | trivinyl- | triethynyl- | tetramethyl | pentamethyl | |
| Gas | borazine | borazine | N,N,N- | N,N,N- | N,N,N- | borazine | borazine | |
| | | | trimethyl | trimethyl | trimethyl | | | |
| | | | borazine | borazine | borazine | | | |
| Carrier Gas | He | He | He | Ar | Ar | He | He | He |
| RF Power (W) | 500 | 400 | 150 | 300 | 100 | 500 | 400 | 150 |
| Vacuum | 1.61 × 10⁻⁷ | 1.41 × 10⁻⁷ | 2.00 × 10⁻⁷ | 1.92 × 10⁻⁷ | 1.36 × 10⁻⁷ | 1.99 × 10⁻⁷ | 2.36 × 10⁻⁷ | 3.07 × 10⁻⁶ |
| Degree | | | | | | | | |
| at 400° C. | | | | | | | | |
| by TDS (Pa) | | | | | | | | |

TABLE 2

| | Comparative | Comparative | Comparative | Comparative | Comparative | Comparative | Comparative | Comparative |
|---|---|---|---|---|---|---|---|---|
| | Example 2 | Example 3 | Example 4 | Example 5 | Example 6 | Example 7 | Example 8 | Example 9 |
| Raw | N,N,N- | B,B,B- | B,B,B- | B,B,B- | B,B,B- | B,N,N,N- | B,B,B,N,N,N- | borazine |
| Material | trimethyl | triethyl | triethyl- | trivinyl- | triethynyl- | tetramethyl | pentamethyl | |
| Gas | borazine | borazine | N,N,N- | N,N,N- | N,N,N- | borazine | borazine | |
| | | | trimethyl | trimethyl | trimethyl | | | |
| | | | borazine | borazine | borazine | | | |
| Carrier Gas | He | He | He | Ar | Ar | He | He | He |
| RF Power (W) | 500 | 400 | 150 | 300 | 100 | 500 | 400 | 150 |
| Vacuum | 2.64 × 10⁻⁵ | 2.07 × 10⁻⁵ | 2.17 × 10⁻⁵ | 2.17 × 10⁻⁵ | 1.32 × 10⁻⁵ | 2.51 × 10⁻⁵ | 2.68 × 10⁻⁵ | — |
| Degree | | | | | | | | |
| at 400° C. | | | | | | | | |
| by TDS (Pa) | | | | | | | | |

TABLE 3

| | Example 10 | Example 11 | Example 12 | Example 13 |
|---|---|---|---|---|
| Raw Material | B,B,B- | B,B,B- | B,B,B- | B,B,B- |
| Gas | tripropyl | triallyl | tributyl | triisobutyl |
| | borazine | borazine | borazine | borazine |
| Carrier Gas | He | He | He | He |
| RF Power (W) | 400 | 400 | 400 | 400 |
| Vacuum | 1.85 × 10⁻⁷ | 1.79 × 10⁻⁷ | 2.20 × 10⁻⁷ | 2.11 × 10⁻⁷ |
| Degree at | | | | |
| 400° C. by | | | | |
| TDS (Pa) | | | | |

TABLE 4

| | Comparative | Comparative | Comparative | Comparative |
|---|---|---|---|---|
| | Example | Example | Example | Example |
| | 10 | 11 | 12 | 13 |
| Raw Material | B,B,B- | B,B,B- | B,B,B- | B,B,B- |
| Gas | tripropyl | triallyl | tributyl | triisobutyl |
| | borazine | borazine | borazine | borazine |
| Carrier Gas | He | He | He | He |
| RF Power (W) | 400 | 400 | 400 | 400 |
| Vacuum | 2.71 × 10⁻⁵ | 2.56 × 10⁻⁵ | 3.15 × 10⁻⁵ | 3.05 × 10⁻⁵ |
| Degree at | | | | |
| 400° C. by | | | | |
| TDS (Pa) | | | | |

Tables 1-4 show that the film formed on the side of the power feed electrode emits less outgas than the film formed on the counter electrode side in any of the cases. In Comparative Example 9, in which borazine (all the R₁ to R₆ are hydrogen in the chemical formula (1)) was used as a raw material and a film was formed on the counter electrode side, white turbidity appears in the film immediately after the substrate was removed from the film forming device, and hence TDS measurement was failed. It seems that this is because the film had extremely high hygroscopicity.

It should be understood that the embodiments and examples disclosed herein are illustrative and not limitative in all aspects. The scope of the present invention is shown not by the description above but by the scope of the claims, and is intended to include all modifications within the equivalent meaning and scope of the claims.

1. A plasma CVD device, comprising:
means for supplying a compound with borazine skeleton;
a plasma generator for generating a plasma; and
means for applying a negative charge to an electrode for placing a substrate.

2. The device according to claim 1, wherein said compound with borazine skeleton is expressed by a chemical formula below. 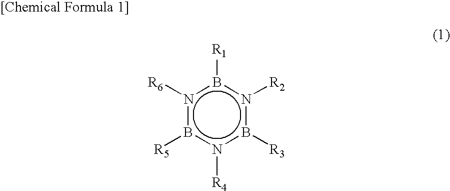
(In the formula, R₁—R₆ may be identical with or different from each other, and are each independently selected from a group consisting of a hydrogen atom, and an alkyl group, an alkenyl group and an alkyl group each having a carbon number of 1-4, on condition that at least one of R₁—R₆ is not the hydrogen atom.)

3. The device according to claim 1 comprising a reaction container for forming a film on the substrate by plasma chemical vapor deposition, and the plasma generator provided outside the reaction container.

4. The device according to claim 1, comprising a reaction container for forming a film on the substrate by plasma chemical vapor deposition, and the plasma generator provided inside the reaction container.

5. The device according to claim 4, wherein the plasma generator s provided at the electrode for placing the substrate.
